(19) United States
(12) Patent Application Publication
(10) Pub. No.: US 2011/0037079 A1
(43) Pub. Date: Feb. 17, 2011

(54) Structure and method for fabricating fluorescent powder gel light emitting module

(75) Inventor: Je-Hsiang Lee, Taipei City (TW)

Correspondence Address: BACON & THOMAS, PLLC, 625 SLATERS LANE, FOURTH FLOOR, ALEXANDRIA, VA, 22314-1176, US

(73) Assignee: PROVISION BUSINESS & TECHNOLOGY CONSULTING SERVICES, INC., Taipei City (TW)

(21) Appl. No.: 12/461,403

(22) Filed: Aug. 11, 2009

(51) Int. Cl. H01L 33/00; H01L 21/56

(52) U.S. Cl. 257/88; 438/27; 257/E21.502; 257/E33.056

(57) ABSTRACT

The present invention relates to a structure and a method for fabricating a fluorescent powder gel light emitting module. A circuit is arranged on a surface of the circuit board, and a plurality of wire connection points is arranged thereon for providing the electrical connection to the electronic components and the light emitting diodes respectively with the circuit board. A plastic ring is formed on an outer portion of the light emitting diodes on the surface of the circuit board to form a specific region and coat the fluorescent powder gel onto the surface of the circuit board in the specific region between every visible light emitting face of the plurality of light emitting diodes and the adjacent region of every light emitting diode, and further to bake for forming a light emitting module to produce light overlapping region by the side light between every adjacent light emitting diode to further produce an extended light source plane to effectively gain a high light emitting efficiency, higher brightness and even irradiation of the radiated light.

### BACKGROUND OF THE INVENTION

1. Field of the invention

The present invention relates to a structure and a method for fabricating a fluorescent powder gel light emitting module, and more particularly, to a light emitting module comprising a plurality of light emitting diode on a circuit board, and fluorescent powder gel coated on the circuit board between every visible light emitting side and every adjacent side of the light emitting diodes in order to produce the light source plane extending from the light source side of every light emitting diode to effectively gain a high light emitting efficiency of the light emitting module.

2. Description of Related Art

There are many styles and types of light emitted diodes (LED). For the sake of the environmental protection, an LED, which consumes less power, and has a smaller size and higher reliability, is being developed. Particularly, a white light LED is widely used in street light, tunnel light, flash light, sign board, household lights and back light of LED panel.

Generally, solar light is a continuous spectrum within a range of 400 to 700 nm, containing red, orange, yellow, green, blue, indigo, and purple color lights, and a general light emitting diodes of the LED can only emit a single color light. For emitting a white light, more than two complementary colors are required to be mixed together. Generally speaking, a white light may be generated by mixing red, green and blue light, the so called three primary colors, by using multiple beads according to a chip packaging process, or coating a fluorescent power with various wave lengths on a blue light or ultraviolet light emitting diodes. The latter method is widely applied in the products available on the market. Therefore, the fluorescent powder is required to be coated to produce the white light.

How LED can evenly and effectively emit brighter light is always an issue for the manufacturers in the field. Light emitting efficiency, external quantum efficiency, and temperature effect of the light emitting diodes are related correspondingly. The external quantum efficiency is a product of the internal quantum efficiency and light extraction efficiency of the components. The internal quantum efficiency is a light conversion efficiency of the components. In other words, the impurity and composition and the structure of the epitaxy are related. The light extractability is a crystal structure of the light emitting diode, which means appearance of the light emitting diodes, surface process, substrate process, package material and electrode arrangement are related to light extractability. The enterprises spend a lot of money in researching on appearance of the light emitting diodes, adhesion technology of the transparent substrate and surface roughness to upgrade the light extractability of the light emitting diodes, in order to gain a better light emitting efficiency.

However, to increase the light emitting efficiency of the light emitting diodes by the methods described above is insufficient, and enterprises also process to increase the light emitting efficiency of the light emitting diodes at a later packaging process. For example, the light emitting diodes arranged into a reflective cup structure. FIGS. 8 and 9 illustrate a sectional side view of a conventional cup LED and an embodiment of a light emission of the conventional LED module. LED A is used in a conventional cannon structure and the LED A comprises light emitting diodes A1 positioned in a cup structure A2. The cup structure A2 has a reflective surface A21, and the light emitting diodes A1 comprises an epoxy package A3 for protecting the light emitting diodes A1. A lens A4 is disposed on a surface of the epoxy package A3. The light emitting diodes A1 can radiate light towards a frontal portion of the lens A4 via the reflective surface 21 to focus the light radiation at a predetermined direction. Furthermore, the LED A is electrically connected to a circuit board B with electrical components to form the light emitting module. However, every light emitting diode A1 arranged in the cup structure A2 and the lens A4 of the LED A can only control a small range light, the lens A4 can only refract partial light irradiated by the light emitting diodes A1 reflected via the reflective surface A21, and the light loss occurred due to the light irradiated at a larger angle can't refract via the lens A4, and thereby form a darker region at the surrounding region and a brighter center. The side light of every light emitting diode A1 may overlap each other, the light emitting module only produce each spot light source, and the side light of the light emitting diode A1 is blocked by the cup structure A2. Thus, not only the reflection cannot be effectively irradiated from the lens A4, a total reflection easily occurs when the fluorescent gel is coated to cause light loss to the light emitting diodes A1 and reduces the light emitting efficiency of the light emitting module.

When the light emitting diodes A1 of the light emitting module emits light, the light generated by each light emitting diode A1 partially overlaps to cause uneven light radiation, and the glare occurs due to the uneven light radiation.

On the other hand, the gel form epoxy A3 is injected as a package after coating the fluorescent gel on the LED A to form two layers of the gel on the LED A. The two layers of the gel on the LED A usually cause poor heat dissipation due to epoxy A3 seal around the light emitting diodes A1, as well as affecting the light emitting efficiency and shorten life span of the LED A. Furthermore, the epoxy A3 seal causes accumulation of heat in the light emitting diodes A1 easily to turn the color of the epoxy A3 yellowish to affect the light penetration ability and accordingly to weaken the light emitting efficiency.

Therefore, how to overcome the above defect is the target for the manufactures in the field.

### SUMMARY OF THE INVENTION

An object of the present invention is to provide a structure and a method for fabricating a fluorescent powder gel light emitting module.

According to an aspect of the present invention, fluorescent powder is coated to promote a light emitting efficiency of light emitting diodes arranged on a surface of the circuit board. A plurality of wire connection points is disposed on circuit board for providing electrical connections to the electronic components and the light emitting diodes respectively with the circuit board. A plastic ring is formed on an outer portion of the light emitting diode on a surface of the circuit board to cover a predetermined region defined by the plastic ring with the fluorescent powder gel. Thus, the fluorescent powder gel is coated onto the surface of the circuit board in the predetermined region between every visible light emitting face of the plurality of light emitting diodes and the adjacent region of every light emitting diode. Further, the resulting structure is baked for forming the fluorescent powder gel onto the surface of the circuit board in the predetermined region, between every visible light emitting face of the plurality of light emitting diodes and the adjacent region of every light emitting diode in order to produce the light source plane extending from the light source side of every light emitting diode to effectively gain a high light emitting efficiency of the light emitting module, and the light emitting module can evenly radiate full face of the light.

According to another aspect of the present invention, the light emitting module with the LED is formed by coating the fluorescent powder gel on the circuit board between every visible light emitting side and every adjacent side of the light emitting diodes doesn't require a process of injecting epoxy or other transparent gel after coating the fluorescent powder gel and the baking process. Thus, not only the accumulation of heat generated by covering two layers of gel onto the surface of the light emitting diodes is reduced but also color changes turning the epoxy yellowish is reduced to effectively increase the life span of the light emitting diodes and reduce the material used to further reduce the fabrication costs.

### BRIEF DESCRIPTION OF THE DRAWING

For a more complete understanding of the present invention, reference will now be made to the following detailed description of preferred embodiments taken in conjunction with the following accompanying drawings.

FIG. 1 is a top view of a structure of a fluorescent powder gel light emitting module (LEM) according to an embodiment of the present invention.

FIG. 2 is a flowchart of a process for fabricating a structure of a fluorescent powder gel LEM according to an embodiment of the present invention.

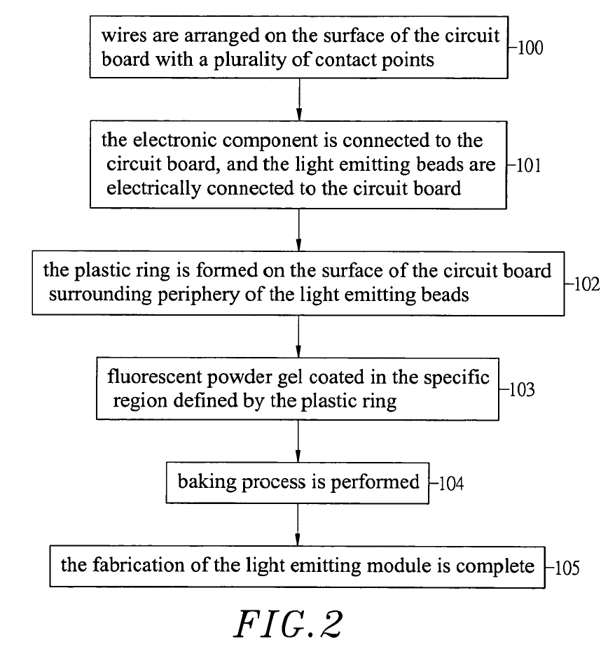

FIG. 3 illustrates a screen printing method for forming a structure of a fluorescent powder gel LEM according to an embodiment of the present invention.

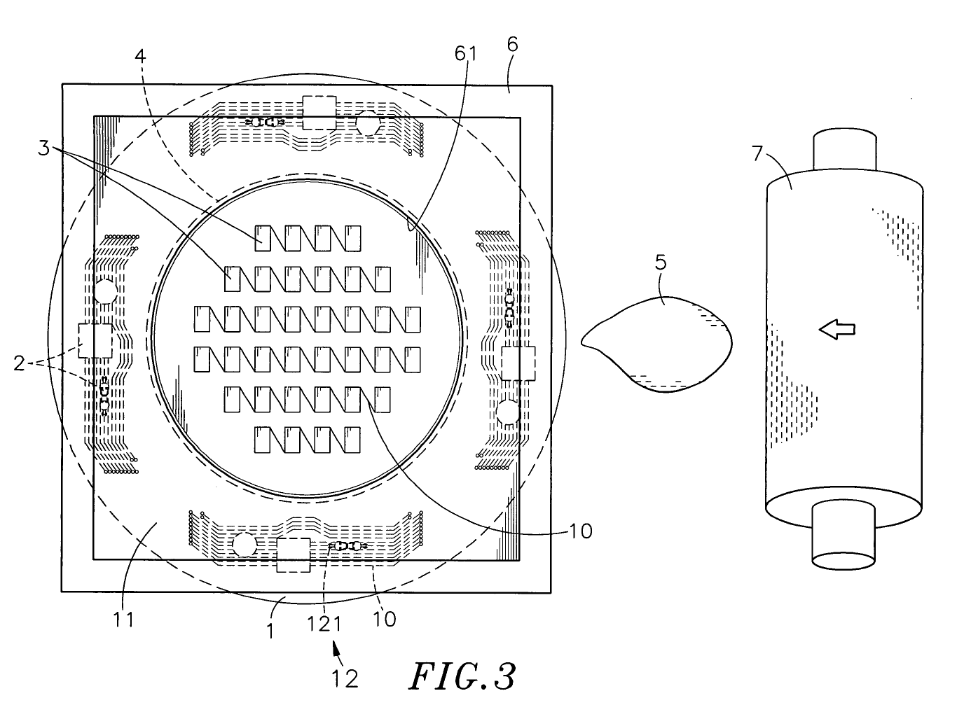

FIG. 4 illustrates a dispensing method for forming a structure of a fluorescent powder gel LEM according to an embodiment of the present invention.

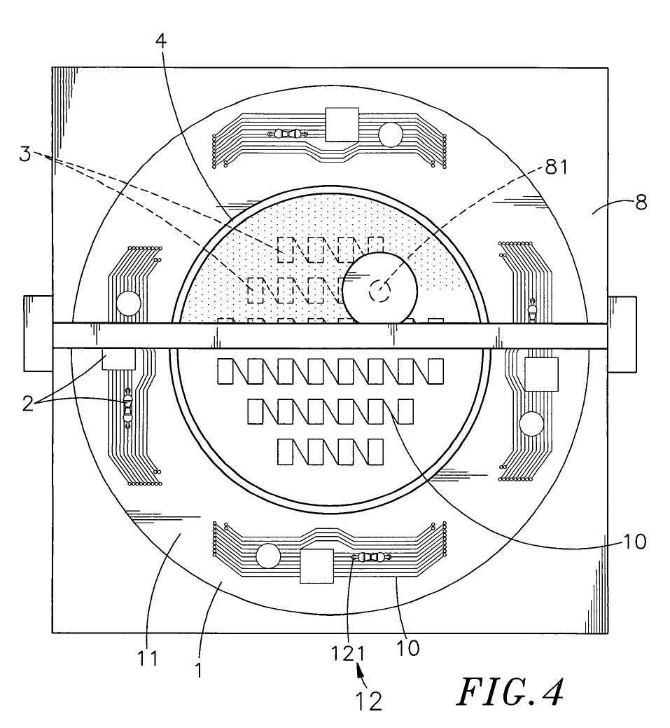

FIG. 5 is a sectional side view illustrating a fabrication of a structure of the fluorescent powder gel LEM according to an embodiment of the present invention.

FIG. 6 illustrates while light processing into various interfaces.

FIG. 7 is a top view of a structure of the fluorescent powder gel LEM according to another embodiment of the present invention.

FIG. 8 is a sectional side view of a conventional cup.

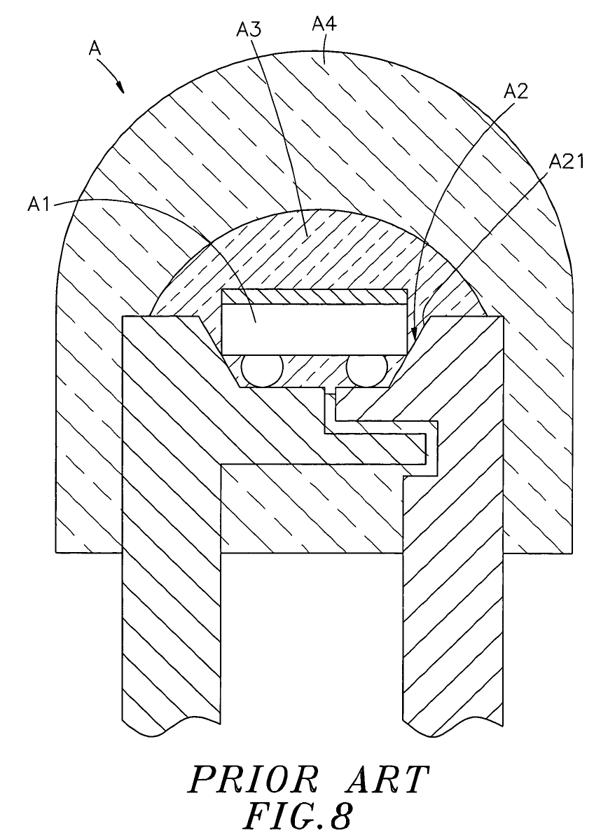

FIG. 9 is an aspect of light emission of a conventional LED module.

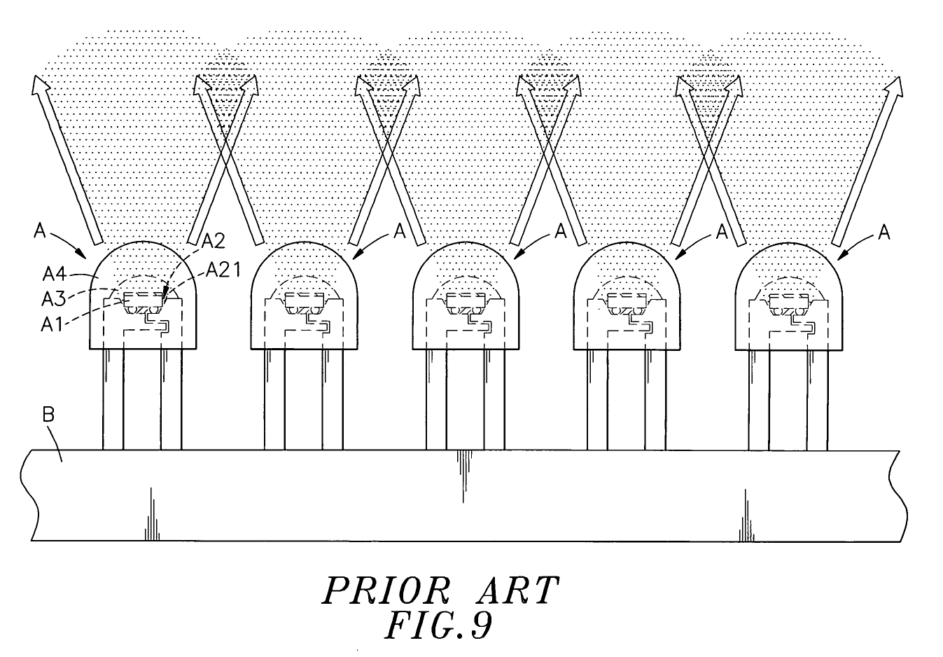

### DETAIL DESCRIPTION OF THE INVENTION

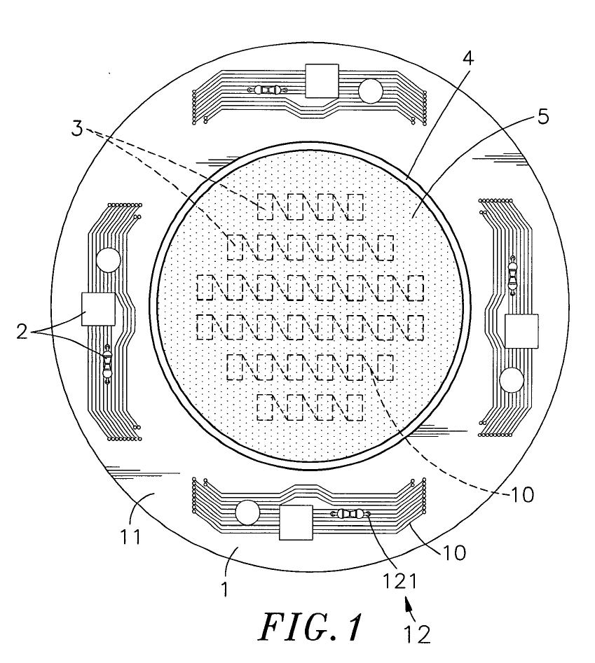

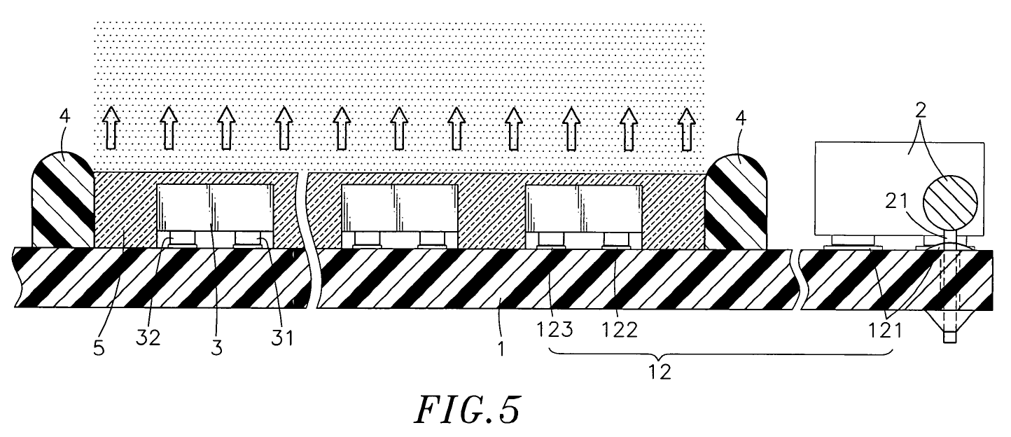

FIGS. 1 and 5 illustrate a top view a structure of a fluorescent powder gel LEM, a method of fabricating the fluorescent gel LEM and a sectional side view of the fluorescent powder gel LEM according to an embodiment of the present invention. The light emitting module comprises a circuit board 1, an electronic component 2, a plurality of light emitting diodes 3, a plastic ring 4 and a fluorescent powder gel 5.

The circuit board 1 comprises a plurality of wires 10 arranged on a surface 11 thereon serving as a circuit. Each of the wires 10 comprises a plurality of wire contact points 12. The wire contact points 12 comprise at least two or more than two component contact points 121 and a plurality of coupled positive contact points 122 and negative contact points 123. The circuit board 1 may have a single sided or the double sided circuit arrangements.

The electronic component 2 comprises a plurality of pins 21 electrically connected to the component contact point 121 of the circuit board 1, and the electronic component 2 may be a capacitor, a resistant or a control chip.

The light emitting diode 3 is a rectangular chip with six faces, and the chip is a flip chip type. The light emitting diode 3 comprises a P type electrode bonding pad 31 and an N type electrode bonding pad 32 on a side of a surface thereof. The light emitting diode 3 can flip chip to electrical connect to the circuit board 1 through the P type electrode bonding pad 31 and the N type electrode bonding pad 32 to couple the positive contact points 122 and the negative contact points 123. The light emitting diode 3 may be plural.

The plastic ring 4 is made of the non-transparent material and positioned on the surface 11 of the circuit board 1 and surrounding the of light emitting diodes 3 on the surface 11 of the circuit board 1 to form a specific area thereon.

The fluorescent powder gel 5 is coated on the specific area formed by the plastic ring 4, and the fluorescent powder gel 5 may cover the light emitting diodes 3 and a portion of the surface 11 of the circuit board 1 between every adjacent light emitting diode 3. The fluorescent powder gel 5 is a mixture containing fluorescent powder and a gel in a specific mixing proportion, and the gel therein can be the transparent or semitransparent adhesive gel selected from epoxy or silicon.

Referring to FIG. 1, 2, 3, 4 and 5, an embodiment of a method of fabricating a fluorescent powder gel LEM of the present invention may be described as follows:

At step 100, the wires 10 are arranged on the surface 11 of the circuit board 1, and the contact points 12, each including a component contact point 121, and a positive contact points 122 and a negative contact points 123, are arranged on the wires 10.

At step 101, the pin 21 of the electronic component 2 is electrically connected to the component contact point 121 of the circuit board 1, and respectively electrically connect the P type electrode bonding pad 31 and the N type electrode bonding pad 32 to the positive contact points 122 and the negative contact points 123 of the circuit board 1.

At step 102, the plastic ring 4 on the surface 11 of the circuit board 1 surrounding the outer portion of the plurality of light emitting diodes 3 is formed.

At step 103, the fluorescent powder gel 5 is coated on the specific area defined by the plastic ring 4 on the circuit board 1. The fluorescent powder gel 5 covers the visible light emitting side of the light emitting diodes 3 and a portion of the surface 11 of the circuit board 1 between every adjacent light emitting diode 3 in the specific area defined by the plastic ring 4.

At step 104, the visible light emitting surface of the light emitting diodes 3 and the portion of the surface 11 of the circuit board 1 between every adjacent light emitting diode 3 coated by the fluorescent powder gel 5 on the circuit board 1 are baked for curing on the visible light emitting face of the light emitting diodes 3 and the portion of the surface 11 of the circuit board 1 between every adjacent light emitting diode 3.

The above method of fabricating the circuit 10 on the surface 11 of the circuit board 1, and electrical connection of the component contact points 121 with the pins 21 of the electronic component 2, and the method to flip chip for the light emitting diodes 3 to respectively electrically connect the P type electrode bonding pad 31 and the N type electrode bonding pad 32 to the positive contact points 122 and the negative contact points 123 of the circuit board 1, and to create five visible light emitting faces; the circuit board 1 can have single sided or double sided circuit arrangements, including the electronic component 2 and the light emitting diode 3 electrically connected on one side of the circuit board 1 to form the single light emitting side, or to electrically connect the light emitting diode 3 on the both sides of the circuit board 1 to form the double light emitting sides. The light emitting diode 3 can be screened in advance before electrically connecting to the circuit board 1 to classify the good product and the bad product, and then electrically connect the good product to the circuit board 1. The interface for electrically connecting the electronic component 2 with the light emitting diode 3 can be the silver paste or welding material, for example, a tin solder or a tin paste. The electronic component 2 may be electrically connected to the circuit board 1 by the surface mounting technology (SMT) or a through hole. The light emitting diode 3 may be electrically connected to the circuit board 1 by the surface mounting technology (SMT), and after the electronic component 2 and the light emitting diode 3 securely electrically connected to the circuit board 1, the plastic ring 4 on the surface 11 of the circuit board 1 is formed. The method for forming the plastic ring 4 may be a dispensing or casting, and the plastic ring 4 surrounds an outer portion of the plurality of the light emitting diodes 3. On the other hand, the procedure for electrically connecting the electronic component 2 to the circuit board 1 may be completed before or after forming the fluorescent powder gel 5. The above process is merely for demonstrating an embodiment of the present invention. The sequence of processing the electronic component 2 is not limited as in claim in the present invention.

The fluorescent powder gel 5 is coated in the specific area defined by the plastic ring 4. The coating method may be a screen printing, a dispensing, a casting or a mold casting process. The methods applied in the present invention, such as screen printing or dispensing process, are merely for demonstration a preferred embodiment. When using the screen printing method, a mesh steel plate 6 with a predetermined thickness is used for covering on the circuit board 1, and the mesh steel plate 6 comprises a through aperture 61 for positioning the light emitting diode 3 positioned on the specific area on the circuit board 1 defined by the plastic ring 4 to position the fluorescent powder gel 5 in front of a roller 7. Furthermore, a roller 7 is used to push and press the fluorescent powder gel 5 into the through aperture 61, to completely cover the fluorescent powder gel 5 onto the five visible light emitting faces of the light emitting diode 3 and a portion of the surface 11 of the circuit board 1 between every adjacent light emitting diode 3 in the specific area on the circuit board 1 defined by the plastic ring 4. The above method of using the roller 7 to dispose the fluorescent powder gel 5 into the through aperture 61 of the mesh steel plate 6 can effectively prevent the formation and entrapment of air bubbles produced due to incoming air while the light emitting diode 3 adheres to the fluorescent powder gel 5, and the fluorescent powder gel 5 can completely cover onto the five visible light emitting faces of the light emitting diode 3 and the portion of the surface 11 of the circuit board 1 between every adjacent light emitting diode 3 for the further baking process. After removing the mesh steel plate 6, the fluorescent powder gel 5 can be formed onto the five visible light emitting faces of the light emitting diode 3 and the portion of the surface 11 of the circuit board 1 between every adjacent light emitting diode 3.

When using dispensing method, a dispenser 8 is required. The dispenser 8 comprises an injection head 81 for injecting the fluorescent powder gel 5 onto the five visible light emitting faces of the light emitting diode 3 and the portion of the surface 11 of the circuit board 1 between every adjacent light emitting diode 3 in the specific area on the circuit board 1 defined by the plastic ring 4. Thereafter, the baking process is performed to curing the fluorescent powder gel 5 onto the five visible light emitting faces of the light emitting diode 3 and the portion of the surface 11 of the circuit board 1 between every adjacent light emitting diode 3.

The above baking process includes heating in an oven to quickly melt the fluorescent powder gel 5 covered onto every visible light emitting face of the light emitting diode 3 and evenly adhere to every visible light emitting faces of the light emitting diode 3 and the portion of the surface 11 of the circuit board 1 between every adjacent light emitting diode 3 in the specific area on the circuit board 1 defined by the plastic ring 4.

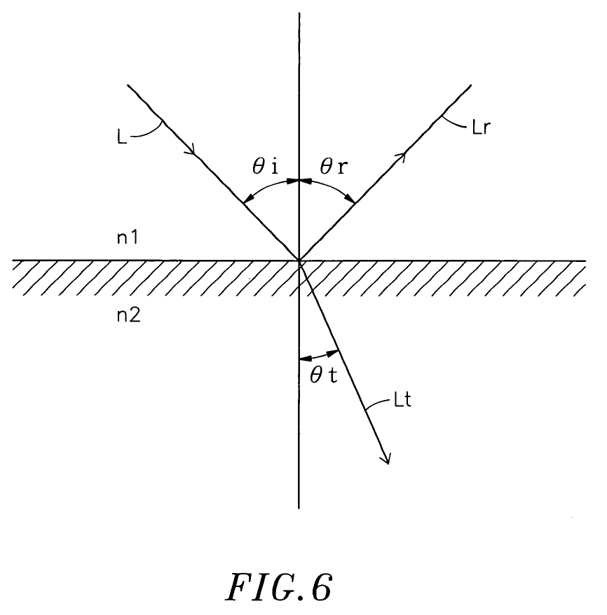

Referring to FIG. 1, 5 and 6, the Snell's Law, the very important geometrical optics law, describes a relationship while the light radiates with various interfaces. As FIG. 6 shows, the interface n1 and n2 have different refractive index; part of light Lt penetrates through the interface n2. According to Snell's Law, there are formule should be followed, θi=θrn1 sin θi−n2 sin θr, θi, θr, θt respectively represent the incidence angle, the reflection angle and the refraction angle. The above n1 and n2 respectively represent the refractive index of the interface n1 and n2. According to the above theory, when the fluorescent powder gel 5 formed on every visible light emitting face of the light emitting diode 3 on the circuit board 1, the side light of every light emitting diode 3 turns into the white light. Because the distance between every light emitting diode 3 is small, light produced in the adjacent side of every light emitting diode 3 may be overlapped. And because the surface 11 of the circuit board 1 between every adjacent light emitting diode 3 also are coated with the fluorescent powder gel 5, the side light of every adjacent light emitting diode 3 generates the extending radiated light. Because of the interface (such as the fluorescent powder gel 5) with the same refractive index, and further generates the extending light source plane, and accordingly, every adjacent light emitting diode 3 on the circuit board 1 generates a light source plane towards the outer portion of the circuit board 1 but the respective light spot. Thus, the convention defect of having the partial reflection or full refraction easily caused when the side light of every adjacent light emitting diode 3 entering into the interface with the different refraction index, which cause the light loss, as well as upgrading the light emitting efficiency with the even emitted light and less glare may be effectively resolved.

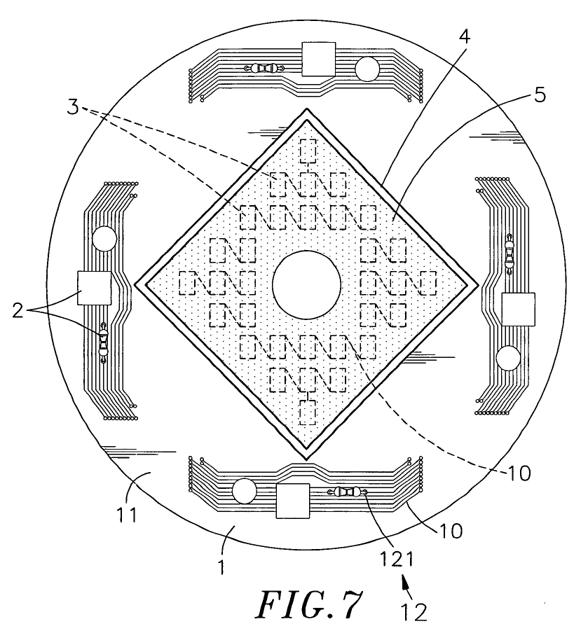

FIG. 7 illustrates a top view of a structure of the fluorescent powder gel LEM according to another embodiment of the present invention. The light emitting diodes 3 electrically connected to the circuit board 1 may be arranged in a circle, a diamond or other shape, and the plastic ring 4 may be disposed at the outer side of the plurality of light emitting diodes 3 on the surface 11 of the circuit board 1 and the fluorescent powder gel 5 may be coated in the specific area defined by the plastic ring 4 to form the fluorescent powder gel 5 in various shapes, for example, circle or diamond shape, on the circuit board 1. However, the above description is merely for demonstrating the preferred embodiment of the present invention. Any specific area defined by the light emitting module or the plastic ring 4 formed on the surface 11 of the circuit board 1 is not for limiting the scope of the present invention. Therefore, the fluorescent powder gel 5 may be coated on the plastic ring 4 to mark the specific area to further make the fluorescent powder gel 5 to evenly cover onto every visible light emitting faces of the light emitting diode 3 and the portion of the surface 11 of the circuit board 1 between every adjacent light emitting diode 3 shall be construed to be within the scope of the present invention.

The structure and the method for fabricating the fluorescent powder gel LEM has at least the following advantages.

The wire contact points 12 are electrically connected to the circuit board 1 with the electronic components 2 and the light emitting diodes 3, and the plastic ring 4 is formed at the outer side of the light emitting diode 3 on the surface 11 of the circuit board 1 and the fluorescent powder gel 5 is formed onto every visible light emitting faces of the light emitting diode 3 and the portion of the surface 11 of the circuit board 1 between every adjacent light emitting diode 3 for forming a light emitting module. The coating of the fluorescent powder gel 5 enables to generate the extended light resource plane after overlapping the side light of every light emitting diode 3, and thereby promote the light emitting efficiency of the light emitting diode 3, as well as enable full face of the emitted light radiated by the light emitting module.

The light emitting diode 3 can be screened in advance before electrically connecting to the circuit board 1 for electrically connecting only the good product to the circuit board 1, and then perform the coating and baking processes of the fluorescent powder gel 5, and thus prevent covering the fluorescent powder gel 5 onto the damaged light emitting diode 3 to waste the fluorescent powder gel 5, saving the fabrication cost.

The light emitting diode 3 of the present invention is directly connected to the circuit board 1, and the process of injecting the transparent gel like epoxy is not necessary to proceed after coating and baking the fluorescent powder gel 5, the light emitting module can be formed after coating and baking the fluorescent powder gel 5 to reduce the heat accumulation of the light emitting diode 3 caused by the dual layer epoxy. Thus, the life span of the light emitting module may be effectively increased, and also minimize the color changes from turning the epoxy yellowish to effectively increase the life span of the light emitting diodes and to reduce the material and manufacturing costs.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What the invention claimed is:

1. A method for fabricating a fluorescent powder gel light emitting module, said light emitting module comprising a circuit board, a plurality of electronic components and a plurality of light emitting diodes, said method comprising:
(A) arranging a plurality of wire on a surface of said circuit board, and arranging a plurality of component contact points, positive contact points and negative contact points on said wires;
(B) respectively electrically connecting via flip chip to a P type electrode bonding pad and an N type electrode bonding pad formed by said plurality of light emitting diodes to said positive contact points and said negative contact points;
(C) forming a plastic ring on said surface of said circuit board surrounding an outer portion of said plurality of light emitting diodes;
(D) coating said fluorescent powder gel in a specific area defined by said plastic ring on the circuit board, a plurality of visible light emitting face of said light emitting diodes and a portion of said surface of said circuit board between every adjacent light emitting diode; and
(E) baking said visible light emitting side of said light emitting diodes and a portion of said surface of said circuit board between every adjacent light emitting diode coated by said fluorescent powder gel on said visible light emitting face of said light emitting diodes and said surface of said circuit board between every adjacent light emitting diode.

2. The method for fabricating a fluorescent powder gel light emitting module according to claim 1, wherein said electronic components are electrically connected to said component contact point through pins before or after said formation of said fluorescent powder gel.

3. The method for fabricating a fluorescent powder gel light emitting module according to claim 2, wherein said step of electrically connecting said pins of said electronic component to said component contact point of said circuit board includes a surface mounting technology or though hole.

4. The method for fabricating a fluorescent powder gel light emitting module according to claim 2, wherein said pin of said electronic components respectively electrically connect to said component contact points of said circuit board through a silver paste.

5. The method for fabricating a fluorescent powder gel light emitting module according to claim 4, wherein said welding material includes tin paste.

6. The method for fabricating a fluorescent powder gel light emitting module according to claim 4, wherein said welding material includes tin solder.

7. The method for fabricating a fluorescent powder gel light emitting module according to claim 1, wherein said P type electrode bonding pad and said N type electrode bonding pad of said light emitting diode are respectively electrically connected to said positive contact points and said negative contact points of said circuit board through a silver paste.

8. The method for fabricating a fluorescent powder gel light emitting module according to claim 7, wherein said welding material includes tin paste.

9. The method for fabricating a fluorescent powder gel light emitting module according to claim 7, wherein said welding material includes tin solder.

10. The method for fabricating a fluorescent powder gel light emitting module according to claim 1, wherein said step of coating said fluorescent powder gel includes screen printing using a mesh steel plate with a predetermined thickness and comprises a through aperture, and when said mesh steel plate covers onto said circuit board, said specific area defined by the plastic ring is within said aperture, the fluorescent powder gel is positioned in front of a roller and said roller pushes and presses said fluorescent powder gel into the through aperture and completely cover a visible light emitting face of the light emitting diode and said surface of said circuit board between every adjacent light emitting diode, and performing a baking process, and wherein after removing said mesh steel plate, said fluorescent powder gel is formed onto every visible light emitting face of said light emitting diode and said surface of said circuit board between every adjacent light emitting diode.

11. The method for fabricating a fluorescent powder gel light emitting module according to claim 1, wherein said step of coating said fluorescent powder gel includes dispensing, wherein a dispenser having an injection head is used for injecting said fluorescent powder gel onto said visible light emitting faces of said light emitting diode and the said surface of said circuit board between every adjacent light emitting diode.

12. The method for fabricating a fluorescent powder gel light emitting module according to claim 1, wherein said baking step is implemented in an oven for heating and to cover said fluorescent powder gel onto said light emitting faces of said light emitting diodes.

13. A structure of a fluorescent powder gel light emitting module comprising a circuit board, a plurality of electronic components, a plurality of light emitting diodes, a plastic gel and said fluorescent powder gel; wherein
said circuit board comprises a plurality of wires arranged on a side thereof for forming a circuit, and said wires comprise a plurality of contact points;
said electronic component comprises a plurality of pins for electrically connecting to said wire contact points;
said light emitting diodes comprise a P type electrode bonding pad and an N type electrode bonding pad in a flip chip type for electrically connecting to said wire contact points;
said plastic ring is made of nontransparent material and is positioned on a surface of said circuit board surrounding an outer portion of said light emitting diodes, and forming a specific area on said circuit board; and
said fluorescent powder gel covers said light emitting diodes and a surface of said circuit board between every adjacent light emitting diode positioning in said specific area.

14. The fluorescent powder gel light emitting module accordingly to claim 13, wherein said plurality of wire contact points comprise a plurality of component contact points and coupled positive and negative electrode contact points.

15. The fluorescent powder gel light emitting module accordingly to claim 14, wherein said P type electrode bonding pads and N type electrode bonding pads of said plurality of light emitting diodes are respectively electrically connected to said positive and negative electrode contact points.

16. The fluorescent powder gel light emitting module accordingly to claim 14, wherein said electronic components comprise a plurality of pins for electrically connecting to said component contact points.

17. The fluorescent powder gel light emitting module accordingly to claim 13 wherein said circuit board is single sided or double sided.

18. The fluorescent powder gel light emitting module accordingly to claim 13 wherein said plurality of light emitting diodes electrically connected to said circuit board are arranged in a circular or a diamond shape, and said fluorescent powder gel forms a circular or a diamond shape on said circuit board.
